(19) United States
(12) Patent Application Publication
(10) Pub. No.: US 2008/0290956 A1
(43) Pub. Date: Nov. 27, 2008

(54) SURFACE-MOUNT TYPE CRYSTAL OSCILLATOR

(75) Inventor: Atsushi HORIE, Saitama (JP)

Correspondence Address: CANTOR COLBURN, LLP, 20 Church Street, 22nd Floor, Hartford, CT, 06103, US

(73) Assignee: NIHON DEMPA KOGYO CO., LTD., Tokyo (JP)

(21) Appl. No.: 12/124,948

(22) Filed: May 21, 2008

(30) Foreign Application Priority Data
May 22, 2007 (JP) JP2007-135967

(51) Int. Cl. H03B 1/00

(52) U.S. Cl. 331/68

(57) ABSTRACT

A surface-mount type crystal oscillator includes a container body having a recess and made up of laminated ceramic, a crystal blank accommodated in the container body, and an IC chip made up of a semiconductor substrate in which at least an oscillation circuit using the crystal blank is formed. The IC chip is electrically and mechanically connected to an inner bottom surface of the recess so that a circuit formation surface thereof faces the inner bottom surface. The IC chip has a first electrode formed on a surface thereof which is opposite the inner bottom surface, and a second electrode is formed on a surface which is disposed in the recess, the first and second electrodes being connected together by wire bonding. Alternatively, an outer peripheral side surface of the IC chip is thermally coupled to an inner peripheral surface of the recess by a conductive adhesive.

### BACKGROUND

1. Field of the Invention

The present invention relates to a surface-mount type crystal oscillator, and in particular, to a surface-mount type crystal oscillator which exerts an improved effect of heat dispersion from an IC (Integrated Circuit) chip incorporated in the oscillator.

2. Description of the Related Arts

A surface-mount type quartz crystal oscillator uses a container for surface mounting and is composed of a quartz crystal blank and an IC (Integrated Circuit) chip having an oscillation circuit that uses the crystal blank, the crystal blank and the IC chip being integrated together. Such a surface-mount type crystal oscillator is small in size and light in weight and is thus widely used in portable electronic equipment typified particularly by cellular phones as a reference source for frequency or time. In recent years, with the further reduced size of the portable electronic equipment with the built-in surface-mount type crystal oscillator, there has been a demand for a smaller surface-mount type crystal oscillator. However, with the increasingly reduced size of the surface-mount type crystal oscillator, heat from an IC chip has started to pose a problem as described below.

FIG. 1A is a sectional view showing an example of the configuration of a surface-mount type crystal oscillator of a related art. FIG. 1 B is a plan view of the crystal oscillator with a cover and a crystal blank removed therefrom.

The illustrated surface-mount type crystal oscillator uses container body 1 having a recess in which IC chip 2 and crystal blank 3 are accommodated. The recess is closed by cover 4 to hermetically seal IC chip 2 and crystal blank 3 in container body 1. Container body 1 is made up of laminated ceramics having lower wall 1a shaped like a substantially rectangular flat plate, intermediate frame 1b provided on bottom wall 1a, and upper wall 1c provided on intermediate frame 1b. Each of intermediate frame 1b and upper wall 1c has an opening formed in a central portion thereof. The opening in intermediate frame 1b is smaller than that in upper wall 1c. In this configuration, the openings in intermediate frame 1b and upper wall 1c form the recess of container body 1. Furthermore, a step portion is formed on an inner wall of the recess at each of the opposite ends of the recess. One of the paired step portions thus formed has a pair of crystal holding terminals 6 provided on a top surface thereof and used to hold crystal blank 3 and to establish an electric connection to crystal blank 3. External terminal 7 is formed in each of four corners of an outer bottom surface of container body 1 and used to surface-mount the crystal oscillator on a circuit board of the equipment which uses this crystal oscillator.

A plurality of circuit terminals 5 for electric connection to IC chip 2 are formed on an inner bottom surface of the recess of container body 1 as circuit patterns. Specifically, circuit terminals 5 include a pair of crystal connection terminals provided on an almost central portion of the inner bottom surface, and a power supply terminal, an oscillation output terminal, a ground terminal, and a standby terminal arranged close the opposite ends of the recess as viewed from the crystal connection terminals. The crystal connection terminals are electrically connected to crystal holding terminals 6 via conductive paths formed in container body 1. Circuit terminals 5 other than the crystal connection terminals are electrically connected to external terminals 7 on the outer bottom surface of container body 1 via conductive paths formed in container body 1.

IC chip 2 is substantially rectangular and is formed by integrating at least an oscillation circuit that uses crystal blank 3 on a semiconductor substrate. Here, a circuit formation surface refers to one of both major surfaces of IC chip 2 which corresponds to a surface of the semiconductor substrate on which the electronic circuit such as the oscillation circuit is formed. A plurality of IC terminals for connecting IC chip 2 to an external circuit are also formed on the circuit formation surface. IC chip 2 is secured to the bottom surface of the recess by joining the IC terminals to circuit terminals 5 on the bottom surface of the recess of container body 1 by, for example, a flip chip bonding technique such as ultrasonic thermocompression bonding using bumps 8 so that the circuit formation surface faces the bottom surface of the recess. As a result, the electronic circuit in IC chip 2 is electrically connected to crystal holding terminals 6 and external terminals 7 via circuit terminals 5.

As shown in FIG. 1 C, crystal blank 3 is, for example, a substantially rectangular AT-cut quartz crystal blank. Excitation electrode 9 is provided on each of both major surfaces of the crystal blank 3. Lead-out electrode 10 extends from each of excitation electrodes 9 to a corresponding one of the opposite sides of one end of crystal blank 3. The opposite sides of the end of crystal blank 3 to which lead-out electrodes 10 extend are secured, by conductive adhesive 11, to respective crystal holding terminals 6 on the top surface of the corresponding one of the step portions provided on the inner wall of container body 1. Crystal blank 3 is thus held horizontally in the recess as shown in FIG. 1A. Crystal blank 3 is electrically connected to the oscillation circuit in IC chip 2 via crystal holding terminals 6 and the circuit terminals 5. Other end of the crystal blank 3 is positioned above the other step portion of the pair of step portions, provided on the inner wall of the container body 1. When the tip end portion of crystal blank 3 is thus positioned between the step portion of container body 1 and cover 4, even if a mechanical impact is applied to the crystal oscillator to rock crystal blank 3, the range of the rock can be reduced.

As described above, IC chip 2 and crystal blank 3 are arranged in the recess of container body 1, and cover 4 is then joined to a surface around the opening of the recess of container body 1 by seam welding, glass sealing, or the like. Thus, IC chip 2 and crystal blank 3 are hermetically sealed in the recess to complete the surface-mount type crystal oscillator.

The temperature characteristic of the oscillation frequency of the crystal oscillator depends on the frequency-temperature characteristic of vibration of crystal blank 3 as a crystal element. Since the AT-cut quartz crystal blank is used as crystal blank 3, the frequency-temperature characteristic of crystal blank 3 is represented as a cubic curve having an inflection point close to the room temperature, +25° C. as shown with curve A in FIG. 2. In FIG. 2, a variation in frequency caused by temperature is represented as the ratio of a deviation Δf to a reference frequency f, that is, Δf/f. The coefficients of the third, second and first-order terms of the cubic curve, indicating the frequency-temperature characteristic, vary depending on a slight variation in the cutting orientation in which the crystal blank is cut off from a block of quartz crystal. In the example shown in FIG. 2, the cutting orientation is adjusted such that temperature T1 corresponding to the maximal value of the cubic curve, indicating the frequency-temperature characteristic, is a temperature (e.g., −5° C.) which is lower than the room temperature, and such that temperature T2 corresponding to the minimal temperature is a temperature (e.g., +65° C.) which is higher than +25° C. By disposing the maximal point at a temperature lower than the room temperature and the minimal point at a temperature higher than the room temperature, it is possible to reduce a change in oscillation frequency caused by an increase or decrease in the ambient temperature of the crystal oscillator above or below the room temperature, compared to the case in which the frequency-temperature characteristic is represented as a cubic curve not having such a maximal or minimal point. The gradient for the frequency-temperature characteristic is normally set to be gentle within the range of temperatures from temperature T1, the maximal point, to temperature T2, the minimal point, and to be steep within the range of temperatures equal to or lower than T1 or equal to or higher than T2. As a result, the crystal element obtained meets a temperature standard specifying that, for example, the frequency varies by at most 10 ppm within the range of temperatures from −10° C. to +70° C. The frequency-temperature characteristic of the crystal element dominates the frequency-temperature characteristic of the crystal oscillator; the crystal element and the crystal oscillator basically exhibit the same characteristics.

However, in the above-described surface-mount type crystal oscillator, when IC chip 2 operates to generate heat, the temperature in container body 1 also rises. Thus, even when the ambient temperature of the crystal oscillator is +25° C., that is, the room temperature, the temperature of the crystal blank 3 is higher than the ambient temperature. Consequently, the oscillation frequency deviates from a nominal frequency (i.e., reference frequency) prescribed as an oscillation frequency at +25° C. Thus, in the related art, for example, the cutting orientation needs to be pre-changed in anticipation of a deviation of the frequency of the crystal oscillator from the nominal frequency after assembly.

The size of the surface-mount type crystal oscillator has further been reduced to, for example, a planar external size of at most 5.0 mm×3.2 mm and a height of at most 1.2 mm. The internal volume of the recess of the container body 1 has correspondingly been reduced to make the adverse effect of heat from IC chip 2 more profound. Curve B in FIG. 2 indicates the frequency-temperature characteristic representing the relationship between the ambient temperature of the crystal oscillator and the deviation Δf/f of the oscillation frequency which relationship is observed if the adverse effect of heat from IC chip 2 is taken into account. A variation in frequency caused by the heat from IC chip 2 is more significant when the ambient temperature is the higher or lower temperature than when the ambient temperature is equal to the room temperature (close to +25° C.). This is because the gradient for the frequency-temperature characteristic is steep in the vicinity of the lower and upper limits of the operating temperature range of the crystal oscillator. In particular, in a region in which the temperature is equal to or higher than about +80° C., the frequency deviation Δf/f is profound in a positive direction from the reference frequency (i.e., nominal frequency) and the effect of heat acts in the same direction. Thus, the upper limit of the standard for the frequency-temperature characteristic is likely to be exceeded. Consequently, the heat from the IC chip is prone to pose a problem. In contrast, in a lower temperature region in which the temperature is equal to or lower than about −20° C., the effect of the heat from the IC chip acts in a direction in which the oscillation frequency approaches the reference frequency. Thus, in this case, the heat from the IC chip does not particularly pose a problem.

A simple change in the cutting orientation of the crystal blank from the quartz crystal block is insufficient to set the deviation of the oscillation frequency of the crystal oscillator within the range specified in the predetermined standard, not only in the vicinity of the room temperature but also on the high temperature side. Thus, in this case, the productivity of the crystal oscillator may be degraded.

In particular, the configuration in which the IC chip is secured to the container body by flip chip bonding as described above has a smaller actual junction area between the container body and the IC chip than a configuration in which the entire surface of the IC chip which is different from the circuit formation surface is joined to the container body and in which electrodes on the circuit formation surface are led out by wire bonding. Consequently, the former configuration produces a lower heat dispersion effect, thus making the adverse effect of heat from the IC chip more profound.

Japanese Patent Laid-Open No. 2007-67967 (JP-A-2007-67967) relates to a temperature compensated crystal oscillator and discloses the arrangement of a plurality of circuit blocks provided in the IC chip is determined such that the adverse effect of heat generated in each circuit block on the oscillation frequency is reduced.

### SUMMARY OF THE INVENTION

An object of the present invention is to provide a surface-mount type crystal oscillator which reduces the adverse effect of heat from an IC chip on the frequency-temperature characteristic and which thus has improved productivity.

According to a first aspect of the present invention, a surface-mount type crystal oscillator includes: a container body having a recess and comprising laminated ceramic; a crystal blank accommodated in the container body; and an IC chip comprising a semiconductor substrate in which at least an oscillation circuit using the crystal blank is formed, the IC chip being electrically and mechanically connected to an inner bottom surface of the recess so that a circuit formation surface thereof faces the inner bottom surface of the recess, wherein the IC chip has a first electrode formed on a surface thereof which is opposite the circuit formation surface, and a second electrode is formed on a surface which is disposed in the recess, the first electrode and the second electrode being connected together by wire bonding.

This configuration enables heat generated by the IC chip to be dispersed from the circuit formation surface and the opposite surface. Thus, the heat from the IC chip is unlikely to reach the crystal blank, and the frequency-temperature characteristic is unlikely to be affected.

In this configuration, the surface on which the second electrode is formed is, for example, the inner bottom surface of the recess or a surface in the recess which is parallel to the inner bottom surface. In the present invention, an external terminal used to surface-mount the crystal oscillator on a circuit board may be formed on an outer bottom surface of the container body, and the second electrode and the external terminal may be electrically connected together via a conductive path formed in the container body. By doing so, the conductive path then functions as a heat conductor to provide a heat transfer path connecting the second electrode and the external terminal. This can further enhance the heat dispersion effect. For example, a ground terminal may be used as the external terminal, to which the second electrode is connected, in order to avoid adverse effects on the other circuits.

In the above-described crystal oscillator, a configuration may be adopted in which a step portion is formed on an inner wall of the recess of the container body at a first end of the recess, two step portions are formed on the inner wall of the recess at a second end thereof, one end of the crystal blank is secured to a top surface of the step portion on the inner wall of the recess at the first end thereof, the other end of the crystal blank is positioned above the upper step portion on the inner wall of the recess at the second end thereof, and the second electrode is formed on a top surface of the lower step portion on the inner wall of the recess at the second end thereof. This configuration makes it possible to prevent the other end of the crystal blank from contacting a gold wire or the like for wire bonding.

Moreover, in the above-described configuration, an insulating adhesive may be interposed between the circuit formation surface of the IC chip and the inner bottom surface of the container body while a conductive adhesive may be filled into at least a part of a space between an outer peripheral side surface of the IC chip and an inner side surface of the recess. This configuration promotes heat dispersion from the outer peripheral side surface of the IC chip to further enhance the heat dispersion effect of the IC chip. This further reduces the adverse effect of heat from the IC chip on the frequency-temperature characteristic.

According to a second aspect of the present invention, a crystal oscillator for surface mounting includes: a container body having a recess and comprising laminated ceramic; a crystal blank accommodated in the container body; and an IC chip comprising a semiconductor substrate in which at least an oscillation circuit using the crystal blank is formed, wherein a plurality of IC terminals provided on a circuit formation surface of the IC chip are connected, with bumps, to a plurality of circuit terminals provided on an inner bottom surface of the recess, and an insulating adhesive is interposed between the circuit formation surface and the inner bottom surface, and a conductive adhesive is filled into at least a part of a space between an outer peripheral side surface of the IC chip and an inner side surface of the recess.

This configuration promotes heat dispersion from the outer peripheral side surface of the IC chip. This further reduces the adverse effect of heat from the IC chip on the frequency-temperature characteristic.

In the second aspect, the IC chip may have a substantially rectangular shape, the recess of the container body may have a substantially rectangular planar shape, and the IC chip may be located eccentrically in the recess and close to one corner thereof. In this configuration, the conductive adhesive may be filled at a position on two sides sharing the corner. To allow the conductive adhesive to be easily filled between the IC chip and the inner peripheral surface of the recess, a notch portion through which the conductive adhesive is filled may be formed in an inner peripheral surface of the recess.

### BRIEF DESCRIPTION OF THE DRAWINGS

FIG. 1A is a sectional view showing the configuration of a surface-mount type crystal oscillator of the related art;

FIG. 1B is a plan view of the crystal oscillator shown in FIG. 1A in a state that a cover and a crystal blank have been removed;

FIG. 1C is a plan view showing the crystal blank;

FIG. 2 is a graph showing an example of the frequency-temperature characteristic of a crystal element or a crystal oscillator;

FIG. 3A is a sectional view showing the configuration of a surface-mount type crystal oscillator according to a first embodiment of the present invention;

FIG. 3B is a plan view of the crystal oscillator shown in FIG. 3A in a state that a cover and a crystal blank have been removed;

FIG. 4A is a sectional view showing the configuration of a surface-mount type crystal oscillator according to a second embodiment of the present invention; and

FIG. 4B is a plan view of the crystal oscillator shown in FIG. 4A in a state that a cover and a crystal blank have been removed.

### DETAILED DESCRIPTION OF THE PREFERRED EMBODIMENTS

### First Embodiment

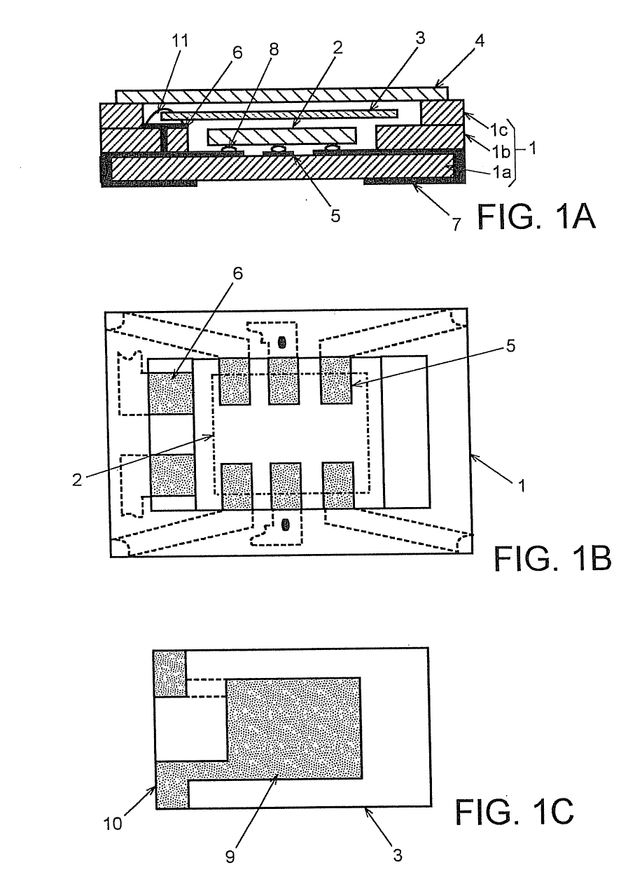

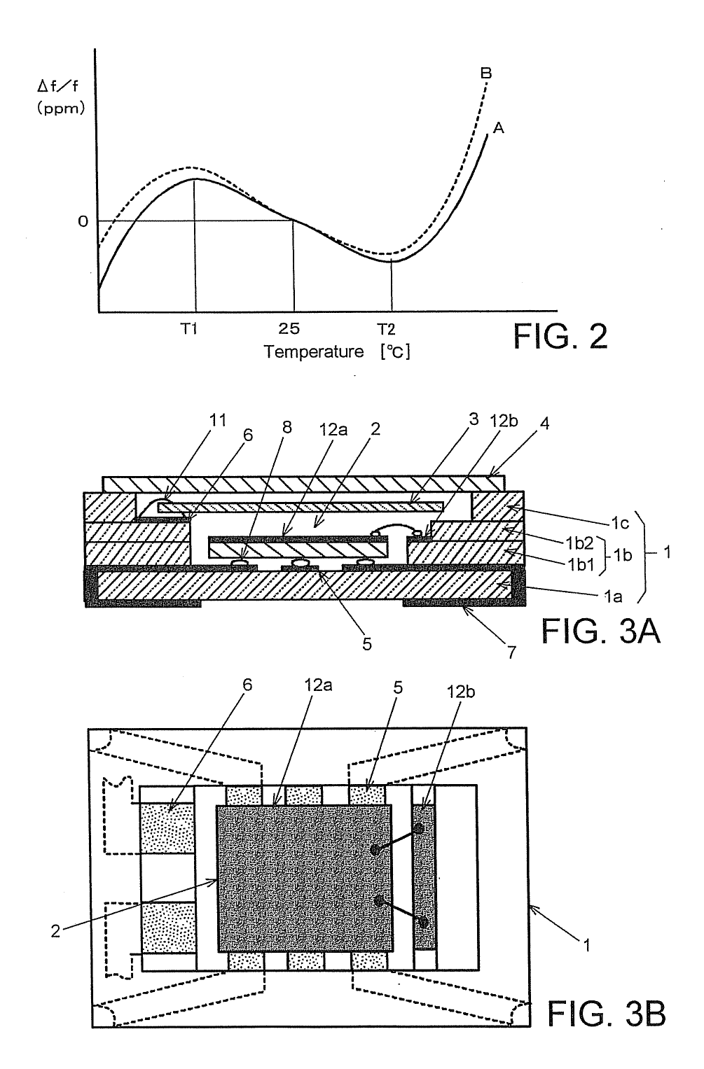

In FIGS. 3A and 3B showing a surface-mount type crystal oscillator according to a first embodiment of the present invention, the same components as those in FIGS. 1A and 1B are denoted by the same reference numerals and duplicate descriptions are omitted or simplified.

The crystal oscillator according to the first embodiment is similar to that shown in FIGS. 1A and 1B and uses container body 1 shaped substantially like a rectangular parallelepiped and having a recess formed in one major surface of container body 1. IC chip 2 and crystal blank 3 are accommodated in the recess. Cover 4 is joined to container body 1 to close and hermetically seal IC chip 2 and crystal blank 3 in container body 1. IC chip 2 is secured to an inner bottom surface of the recess by flip chip bonding. In this case, the flip chip bonding, for example, joins circuit terminals 5 provided on the inner bottom surface of the recess to IC terminals provided on a circuit formation surface of IC chip 2, by means of ultrasonic thermocompression bonding using bumps 8. Crystal blank 3 is an AT-cut quartz crystal blank similar to that shown in FIG. 1 C. The opposite sides of the end of crystal blank 3 to which lead-out electrodes 10 extend from excitation electrodes 9 are secured to a top surface of a step portion formed on an inner side surface of the recess at a first end of the recess. Two rows each of three circuit terminals 5, described above, are arranged on the inner bottom surface of the recess. Central circuit terminal 5 in each row is a crystal connection terminal, and the remaining four circuit terminals are a power supply terminal, an output terminal, a ground terminal, and a standby terminal.

The crystal oscillator according to the present embodiment is different from that shown in FIGS. 1A and 1B in that first electrode 12a is provided on a surface of IC chip 2 which is opposite the circuit formation surface and a second electrode 12b is provided in the recess of container body 1, with first electrode 12a on IC chip 2 electrically connected to second electrode 12b on container body 1 by gold (Au) wires or the like for wire bonding. First electrode 1 2a is made up of, for example, gold and formed by vacuum deposition or sputtering. In the present embodiment, intermediate frame 1b is composed of two layers, first layer 1b1 and second layer 1b2 which have respective openings of different sizes formed therein. Thus, a step portion formed on the inner wall of the recess at a second end thereof is composed of two step portions, an upper step portion and a lower step portion. The upper step portion is at the same level as that of the step portion formed on the inner wall of the recess at the first end thereof. The other end of crystal bank 3 is positioned above the upper step portion.

Second electrode 12b is provided on a top surface of the lower step portion formed on the inner wall of the recess at the second end thereof. Such a second electrode 12b is printed in advance on a ceramic green sheet (i.e., unburned ceramic sheet) corresponding to first layer 1b1 when ceramic green sheets are laminated to one another and then burned to form container body 1. Thus, second electrode 12b is formed integrally with container body 1 when the laminated ceramic is burned. After the burning, a surface of second electrode 12b is plated with, for example, gold. In the illustrated example, second electrode 12b is electrically connected to external terminal 5 as a ground terminal via conductive paths including via-holes (not shown).

In this configuration, heat generated by IC chip 2 can be transferred and dispersed to external terminals 5 for grounding via first electrode 12a, the gold wires for wire bonding, and second electrode 12b, even from the surface of IC chip 2 which is opposite the circuit formation surface. That is, the heat is dispersed from both major surfaces of IC chip 2, making it possible to inhibit a rise in the operating temperature of crystal blank 3. This enables a reduction in the adverse effect of heat from IC chip 1 on the frequency-temperature characteristic, thus improving the productivity of the crystal oscillator.

In the above description, second electrode 12b is electrically connected to external terminal 5 as a ground terminal. However, even if second electrode 12b is connected to one of external terminals 5 that is not the ground terminal, a heat transfer path is formed to improve the heat dispersion effect. Furthermore, in the above description, second electrode 12b is formed on the lower step portion on the inner wall of the recess at the second end thereof. However, if there is any space over the inner bottom surface of the recess, second electrode 12b may be formed on the inner bottom surface itself of the recess. In other words, the second electrode may be formed on the inner bottom surface of the recess or on a surface parallel to the inner bottom surface.

Moreover, since heat transferred to second electrode 12b is also dispersed via container body 1, the heat dispersion effect is expected to be exerted without the need to connect second electrode 12b to one of external terminals 5. Furthermore, in the above-described example, the lower step portion, on which second electrode 12b is provided, is formed only at the second end of the recess. However, the lower step portion may also be provided at the first end of the recess or formed all along the circumference of the recess. Then, the second electrode may be formed on the lower step portion and subjected to wire bonding using gold wires to improve the heat dispersion effect.

### Second Embodiment

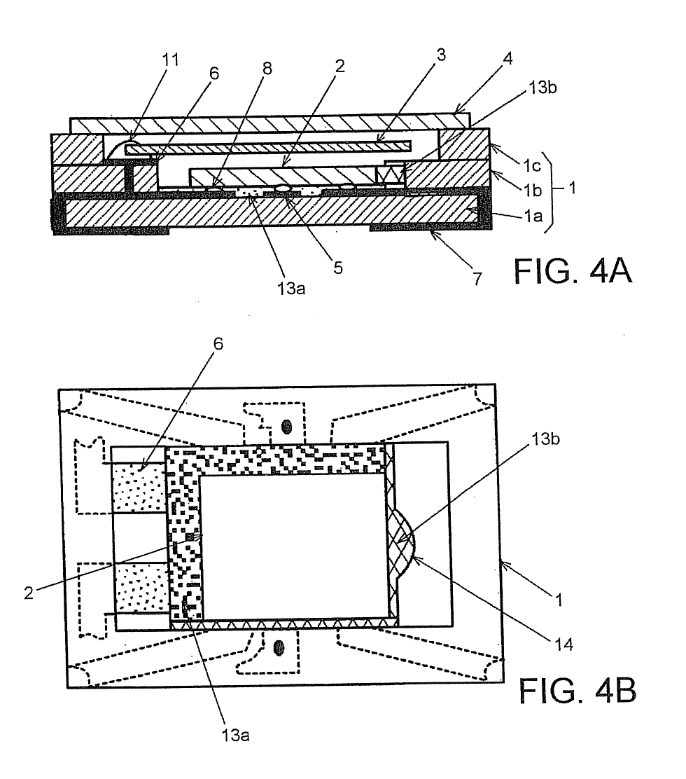

In FIGS. 4A and 4B showing a surface-mount type crystal oscillator according to a second embodiment of the present invention, the same components as those in FIGS. 3A and 3B are denoted by the same reference numerals, and duplicate descriptions are omitted or simplified.

The crystal oscillator according to the second embodiment is similar to that according to the first embodiment except that instead of the gold wires for wire bonding used to improve the efficiency of heat transfer from IC chip 2, a conductive adhesive is interposed between an outer peripheral side surface of the IC chip and an inner side surface of the recess to enhance the thermal coupling between IC chip 2 and container body 1, thus allowing heat generated by IC chip 2 to escape efficiently to the container body 1. Unlike in the case of the first embodiment, intermediate frame 1b of container body 1 is composed of one layer, and only one step portion is formed on the inner wall of the recess of container body 1 at the second end of the recess.

Specifically, IC chip 2 has a substantially rectangular shape, and the recess of container body 1 also has a substantially rectangular planar shape, IC chip 2 is located in the recess so that the IC chip is close to one of the corners thereof. As a result, two adjacent sides of IC chip 2 are arranged close to two adjacent inner peripheral sides of the recess, and the position of the center of IC chip 2 is thus displaced from the center of the inner bottom surface of the recess of container body 1.

Insulating adhesive 13a is interposed between the circuit formation surface of the IC chip and the inner bottom surface of container body 1. Insulating adhesive 13 is provided so as to prevent conductive adhesive 13b described below from electrically connecting to circuit terminals 5 or the IC terminals. Insulating adhesive 13 is formed by, for example, application.

In this configuration, two sides of an outer peripheral side surface of IC chip 2 which share one vertex are closer to the inner peripheral surfaces of the recess than the two other sides. Thus, conductive adhesive 13b is filled into the area between the outer peripheral side surface of IC chip 2 and the inner peripheral surface of the recess of container body 1, which are located close to each other. As a result, conductive adhesive 13b is injected into a groove-like gap portion between the outer peripheral side surface of IC chip 2 and the inner peripheral surface of the recess. In this case, notch portion 14 is formed at a position on the step portion on the inner wall at the second end side of the recess of container body 1 to facilitate injection of conductive adhesive 13b.

This configuration allows the outer peripheral side surface of IC chip 2 and the inner peripheral surface of the recess of container body 1 to be thermally coupled together by conductive adhesive 13b. The conductive adhesive 13b contains, for example, silver particles and thus has a high heat conductivity. Thus, the interposition of conductive adhesive 13b makes it possible to enhance the heat dispersion effect from IC chip 2 to container body 1. The heat dispersion effect can further be enhanced by electrically connecting conductive adhesive 13b to external terminals 5 that are, for example, ground terminals.

In the above-described second embodiment, the heat dispersion effect can further be enhanced by adopting the heat transfer mechanism based on the gold wires for wire bonding, as shown in the first embodiment.

In the surface-mount type crystal oscillator according to the above-described embodiments, IC chip 2 and crystal blank 3 are accommodated in the same space in container body 1. However, this is not the only crystal oscillator to which the present invention is applicable. For example, the present invention is applicable to a crystal oscillator using a container body having an H-shaped cross section with a recess formed in each of the opposite major surfaces thereof, one of the recesses having a crystal blank accommodated therein, the other recess having an IC chip accommodated therein. Moreover, the present invention is also applicable to a surface-mount type crystal oscillator having a mounting substrate joined to a bottom surface of the crystal oscillator, the mounting substrate having a recess with an IC chip accommodated therein.

In the above description, IC chip 2 comprises at least the oscillation circuit using crystal blank 3. However, IC chip 2 may further comprise a temperature compensating mechanism that compensates for the frequency-temperature characteristic of crystal blank 3. If the temperature compensating mechanism is incorporated into the IC chip to configure the surface-mount type crystal oscillator as a surface-mount type temperature compensated crystal oscillator, heat generated in the IC chip may result in a difference between a temperature detected by a temperature detecting element provided in the IC chip and the actual operating temperature of the crystal blank. Then, a temperature compensating voltage generated by the temperature compensating mechanism may deviate from a voltage actually required to compensate for the temperature. Thus, the temperature compensated crystal oscillator needs to appropriately disperse heat from the IC chip. Therefore, the present invention is significantly applicable to the temperature compensated crystal oscillator.

What is claimed is:

1. A surface-mount type crystal oscillator comprising:
a container body having a recess and comprising laminated ceramic;
a crystal blank accommodated in the container body; and
an IC chip comprising a semiconductor substrate in which at least an oscillation circuit using the crystal blank is formed, the IC chip being electrically and mechanically connected to an inner bottom surface of the recess so that a circuit formation surface thereof faces the inner bottom surface of the recess, wherein the IC chip has a first electrode formed on a surface thereof which is opposite the circuit formation surface, and a second electrode is formed on a surface which is disposed in the recess, the first electrode and the second electrode being connected together by wire bonding.

2. The crystal oscillator according to claim 1, wherein the surface on which the second electrode is formed is the inner bottom surface of the recess or a surface in the recess which is parallel to the inner bottom surface.

3. The crystal oscillator according to claim 2, wherein an external terminal used to surface-mount the crystal oscillator on a circuit board is formed on an outer bottom surface of the container body, and the second electrode and the external terminal are electrically connected together via a conductive path formed in the container body.

4. The crystal oscillator according to claim 3, wherein the external terminal to which the second electrode is electrically connected is a ground terminal.

5. The crystal oscillator according to claim 2, wherein a step portion is formed on an inner wall of the recess of the container body at a first end of the recess, and two step portions are formed on the inner wall of the recess at a second end thereof, and
one end of the crystal blank is secured to a top surface of the step portion on the inner wall of the recess at the first end thereof, the other end of the crystal blank is positioned above the upper step portion on the inner wall of the recess at the second end thereof, and the second electrode is formed on a top surface of the lower step portion on the inner wall of the recess at the second end thereof.

6. The crystal oscillator according to claim 2, wherein an insulating adhesive is interposed between the circuit formation surface of the IC chip and the inner bottom surface of the container body, and a conductive adhesive is filled into at least a part of a space between an outer peripheral side surface of the IC chip and an inner side surface of the recess.

7. A crystal oscillator for surface mounting comprising:
a container body having a recess and comprising laminated ceramic;
a crystal blank accommodated in the container body; and
an IC chip comprising a semiconductor substrate in which at least an oscillation circuit using the crystal blank is formed,
wherein a plurality of IC terminals provided on a circuit formation surface of the IC chip are connected, with bumps, to a plurality of circuit terminals provided on an inner bottom surface of the recess, and an insulating adhesive is interposed between the circuit formation surface and the inner bottom surface, and
a conductive adhesive is filled into at least a part of a space between an outer peripheral side surface of the IC chip and an inner side surface of the recess.

8. The crystal oscillator according to claim 7, wherein the IC chip has a substantially rectangular shape, the recess of the container body has a substantially rectangular planar shape, the IC chip is located eccentrically in the recess and close to one corner thereof, and the conductive adhesive is filled at a position on two sides sharing the corner.

9. The crystal oscillator according to claim 8, further comprising a notch portion formed in an inner peripheral surface of the recess and through which the conductive adhesive is filled.
